(19) United States
(12) Patent Application Publication
(10) Pub. No.: US 2021/0398779 A1
(43) Pub. Date: Dec. 23, 2021

(54) APPARATUS, SYSTEM, AND METHOD FOR IMPEDANCE ADJUSTMENT OF PROCESSING STATION

(71) Applicant: Piotech Inc., Shenyang (CN)

(72) Inventors: Giyoul Kim, Shenyang (CN); Junichi Arami, Shenyang (CN); Zhen Liu, Shenyang (CN); Yaxin Zhang, Shenyang (CN); Yinghao Lin, Shenyang (CN); Si Shen, Shenyang (CN)

(21) Appl. No.: 17/350,352

(22) Filed: Jun. 17, 2021

(30) Foreign Application Priority Data
Jun. 21, 2020 (CN) 202010570685.9

(51) Int. Cl. H01J 37/32

(52) U.S. Cl. CPC H01J 37/32183; H01J 2237/032; H01J 37/32532

(57) ABSTRACT

This application relates to an apparatus, a system, and a method for impedance adjustment of a processing station. An apparatus for impedance adjustment of a single processing station may include: a heating plate including a first grounding grid and a second grounding grid, where the first grounding grid and the second grounding grid cover different areas of the heating plate; a first tuner connected to the first grounding grid and including a first adjustable capacitor and a first sensor for detecting a current; and a second tuner connected to the second grounding grid and including a second adjustable capacitor and a second sensor for detecting a current.

### BACKGROUND OF THE INVENTION

### Field of the Invention

This application relates generally to the field of semiconductor manufacturing, and more specifically, to apparatuses, systems, and methods for impedance adjustment of a processing station(s) in a semiconductor processing system.

### Description of the Related Art

With the development of semiconductor manufacturing technologies, a production capacity of the semiconductor processing system and an integrated production capacity of a production machine need to be improved. This requires an increase in the maximum quantity of substrates that can be simultaneously processed by the semiconductor processing system. This can be achieved by increasing the quantity of processing chambers in the semiconductor processing system or by using multi-station processing chambers. The multi-station processing chamber means that a plurality of processing stations can be disposed in one processing chamber. Each processing station can process one substrate, and therefore the multi-station processing chamber can simultaneously process a plurality of substrates.

It is generally desirable to perform the same processing on a plurality of substrates in a multi-station processing chamber and obtain the same film thickness distribution. However, a hardware difference between various processing stations may lead to a difference in radio-frequency impedance, which affects the consistency of processing results. Therefore, a method is needed to reduce the difference between processing results of a plurality of processing stations.

In addition, for a single processing station, how to adjust the film thickness distribution to meet different application needs is also a problem that needs to be considered.

### SUMMARY OF THE INVENTION

To resolve the aforementioned problems, in an implementation of this application, an apparatus for impedance adjustment of a single processing station is provided. The apparatus includes: a heating plate including a first grounding grid and a second grounding grid, where the first grounding grid and the second grounding grid cover different areas of the heating plate; a first tuner connected to the first grounding grid and including a first adjustable capacitor and a first sensor for detecting a current; and a second tuner connected to the second grounding grid and including a second adjustable capacitor and a second sensor for detecting a current.

In some embodiments, the apparatus further includes: a first heating plate radio-frequency electrode, where one end of the first heating plate radio-frequency electrode is connected to the first grounding grid, and the other end of the first heating plate radio-frequency electrode is connected to the first tuner; and a second heating plate radio-frequency electrode, where one end of the second heating plate radio-frequency electrode is connected to the second grounding grid, and the other end of the second heating plate radio-frequency electrode is connected to the second tuner. The first heating plate radio-frequency electrode and the second heating plate radio-frequency electrode can be nickel rods, copper rods, or other similar materials.

In some embodiments, the first grounding grid and the second grounding grid are arranged concentrically. The first heating plate radio-frequency electrode and the second heating plate radio-frequency electrode are symmetrically arranged relative to the center of the first grounding grid and the second grounding grid. In an embodiment, the first grounding grid is above the second grounding grid, a central part of the second grounding grid includes a hollowed-out area at least partially covered by the first grounding grid, a connecting rib is disposed in the hollowed-out area, the second heating plate radio-frequency electrode is connected to the connecting rib, and the first heating plate radio-frequency electrode is connected to the first grounding grid through the hollowed-out area.

In some embodiments, the apparatus further includes an adapting structure. The adapting structure includes: a first radio-frequency adapting structure connecting the other end of the first heating plate radio-frequency electrode to a first access electrode of the first tuner; and a second radio-frequency adapting structure connecting the other end of the second heating plate radio-frequency electrode to a second access electrode of the second tuner. In an embodiment, the first radio-frequency adapting structure includes a first clamping structure and a first spring plate, where one end of the first spring plate is fastened to the first access electrode, and the other end of the first spring plate is clamped and connected to the other end of the first heating plate radio-frequency electrode by using the first clamping structure. The second radio-frequency adapting structure includes a second clamping structure and a second spring plate, where one end of the second spring plate is fastened to the second access electrode, and the other end of the second spring plate is clamped and connected to the other end of the second heating plate radio-frequency electrode by using the second clamping structure. A first horizontal extension part is included between the one end of the first spring plate and the other end of the first spring plate, and a second horizontal extension part is included between the one end of the second spring plate and the other end of the second spring plate.

In some embodiments, the adapting structure further includes an alternating current adapting structure, where one end of the alternating current adapting structure is connected to a heating plate alternating current electrode, the heating plate alternating current electrode is connected to a heating element in the heating plate, and the other end of the alternating current adapting structure is connected to an electrode interface of an alternating current filter. In an embodiment, the one end of the alternating current adapting structure includes a female connector structure with a wire spring inside, and the other end of the alternating current adapting structure includes a male connector structure that can be directly connected to the electrode interface of the alternating current filter. In another embodiment, a position at which the other end of the alternating current adapting structure is connected to the electrode interface of the alternating current filter is below a position at which the first radio-frequency adapting structure is connected to the first access electrode. In still another embodiment, the heating plate alternating current electrode includes: a first pair of heating plate alternating current electrodes connected to a first heating element in the heating plate; and a second pair of heating plate alternating current electrodes connected to a second heating element in the heating plate. The first heating element can correspond to the first grounding grid, and the second heating element can correspond to the second grounding grid.

In some embodiments, the adapting structure further includes an isolation component isolating the alternating current adapting structure from the first radio-frequency adapting structure and the second radio-frequency adapting structure. The isolation component can surround the alternating current adapting structure, or the isolation component can surround the first radio-frequency adapting structure and the second radio-frequency adapting structure. In an embodiment, the isolation component includes an isolation tube or an isolation block.

In some embodiments, the adapting structure further includes a housing for shielding radio frequencies. The housing can include a window used for operating and checking the interior of the adapting structure.

In another implementation of this application, a system for impedance adjustment of a plurality of processing stations is provided. The system includes a plurality of apparatuses for impedance adjustment of a single processing station according to any embodiment of this application, where each apparatus is in one processing station.

In another implementation of this application, a method for impedance adjustment of a single processing station is provided. The processing station includes the apparatus for impedance adjustment of a single processing station according to any embodiment of this application and a radio-frequency electrode plate opposite to the heating plate. The method includes: setting the first adjustable capacitor and the second adjustable capacitor to predetermined capacitance values; supplying radio-frequency power to the radio-frequency electrode plate to form an electric field between the radio-frequency electrode plate and the heating plate; detecting a first current by using the first sensor; detecting a second current by using the second sensor; and adjusting a capacitance value of at least one of the first adjustable capacitor and the second adjustable capacitor based on the first current and the second current, so that the first current and the second current satisfy a predetermined relationship. The predetermined relationship can include that the first current is equal to the second current, the first current is greater than the second current, or the first current is less than the second current. The predetermined relationship can further include that either or both of the first current and the second current are equal to a predetermined value or within a predetermined range.

In another implementation of this application, a method for impedance adjustment of a plurality of processing stations is provided. Each of the plurality of processing stations includes the apparatus for impedance adjustment of a single processing station according to any embodiment of this application and a radio-frequency electrode plate opposite to the heating plate. The method includes: setting the first adjustable capacitor and the second adjustable capacitor in each processing station to predetermined capacitance values; supplying radio-frequency power to the radio-frequency electrode plate in each processing station to form an electric field between the radio-frequency electrode plate and the heating plate in each processing station; performing the following operations for a first processing station in the plurality of processing stations: detecting a first current by using the first sensor of the first processing station; detecting a second current by using the second sensor of the first processing station; and adjusting a capacitance value of at least one of the first adjustable capacitor and the second adjustable capacitor in the first processing station based on the first current and the second current, so that the first current and the second current satisfy a predetermined relationship, where the first current satisfying the predetermined relationship has a first value, and the second current satisfying the predetermined relationship has a second value; and performing the following operations for each of the other processing stations in the plurality of processing stations: adjusting a capacitance value of at least one of the first adjustable capacitor and the second adjustable capacitor in the processing station, so that a current detected by the first sensor of the processing station has the first value, and a current detected by the second sensor of the processing station has the second value. The predetermined relationship can include that the first value is equal to the second value, the first value is greater than the second value, or the first value is less than the second value. The predetermined relationship can further include that either or both of the first value and the second value are equal to a predetermined value or within a predetermined range. In an embodiment, the method further includes: after a current detected by the first sensor of a second processing station in the plurality of processing stations has the first value and a current detected by the second sensor of the second processing station has the second value, fine tuning at least one of the first adjustable capacitor and the second adjustable capacitor of the second processing station.

Details of one or more examples of this application are set forth in the following accompanying drawings and description. Other features, objectives and advantages are apparent according to the description, accompanying drawings, and claims.

### BRIEF DESCRIPTION OF THE DRAWINGS

Disclosure in this specification mentions and includes the following figures:

FIG. 1 is a schematic structural diagram of a semiconductor processing apparatus according to some embodiments of this application;

FIG. 2 is a flowchart of a method for impedance adjustment of a single processing station according to some embodiments of this application;

FIG. 3 is a flowchart of a method for impedance adjustment of a plurality of processing stations according to some embodiments of this application;

FIG. 4A to FIG. 4D are schematic structural diagrams of grounding grids according to some embodiments of this application;

FIG. 5 is a schematic arrangement diagram of heating plate electrodes according to some embodiments of this application;

FIG. 6 is a schematic layout diagram of an alternating current filter and a tuner according to some embodiments of this application; and

FIG. 7A to FIG. 7C are schematic diagrams of an adapting structure according to some embodiments of this application.

According to conventions, various features illustrated in the drawings may not be drawn to scale. Therefore, for clarity, sizes of the various features may be increased or reduced arbitrarily. Shapes of components illustrated in the figures are only exemplary shapes, and do not limit actual shapes of the components. In addition, for clarity, the embodiments illustrated in the drawings may be simplified. Therefore, the drawings may not illustrate all the components of a given device or apparatus. Finally, the same reference numbers may be used throughout this specification and drawings to indicate the same features.

### PREFERRED EMBODIMENT OF THE PRESENT INVENTION

The present invention will be described more fully below with reference to the drawings, and specific exemplary embodiments are shown through examples. However, the claimed subject matter can be implemented in many different forms. Therefore, the construction of the claimed subject matter covered or applied for is not limited to any exemplary specific embodiments disclosed in this specification; and the exemplary specific embodiments are only examples. Likewise, the present invention aims to provide a properly broad scope for the claimed subject matter that is applied for or covered.

The phases “in an embodiment,” “in one embodiment,” “according to an embodiment” or “according to one embodiment” used in this specification are not necessarily referring to the same specific embodiment and do not mean that the technical solutions for which protection is sought need to include all features described in the embodiments, and the phases “in (some) other embodiments” or “according to (some) other embodiments” used in this specification are not necessarily referring to different specific embodiments. The objective is, for example, that the claimed subject matter includes a combination of all or part of specific exemplary embodiments. The terms “including” and “comprising” in this specification are used in an open-ended manner, and therefore is to be interpreted as meaning “including, but not limited to . . . ”. The meanings of “upper” and “lower” in this specification are not limited to the relationship directly presented by the drawings, and is to include descriptions with clear correspondence, such as “left” and “right,” or relationship opposite to “upper” and “lower.” The term “substrate” in this specification is to be understood as being interchangeable with terms such as “wafer,” “die,” “chip,” “silicon wafer,” and the like. This specification uses some terms to refer to specific system components. As those skilled in the art understand, different companies may use different terms to refer to the system components.

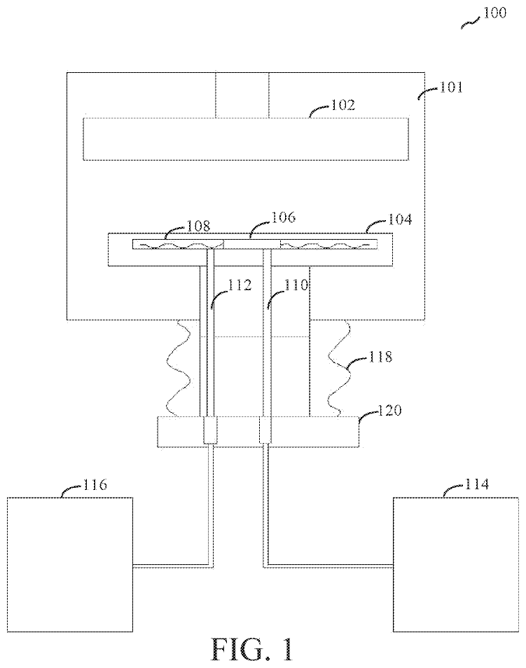

FIG. 1 is a schematic structural diagram of a semiconductor processing apparatus 100 according to some embodiments of this application. The semiconductor processing apparatus 100 is a processing apparatus in a processing station, and includes a reaction chamber 101. A spray plate 102 and a heating plate 104 are disposed in the reaction chamber 101. A substrate to be processed (not shown in the figure) can be placed between the spray plate 102 and the heating plate 104 that are disposed opposite to each other. The spray plate 102 is configured to supply reaction gas to the substrate to be processed. In addition, the spray plate 102 can also be used as a radio-frequency electrode plate. A radio-frequency power supply (not shown in the figure) can supply radio-frequency power to the spray plate 102 through a radio-frequency matcher (not shown in the figure), to form an electric field between the spray plate 102 and the heating plate 104 for processing.

In the example shown in FIG. 1, the heating plate 104 includes a first grounding grid 106 and a second grounding grid 108. The first grounding grid 106 and the second grounding grid 108 can cover different areas of the heating plate 104. As shown in FIG. 1, the first grounding grid 106 can be located in a central part of the heating plate 104, and the second grounding grid 108 can be located in a marginal part of the heating plate 104. The first grounding grid 106 is a circular grid, and the second grounding grid 108 is an annular grid. The first grounding grid 106 and the second grounding grid 108 can be arranged concentrically. FIG. 1 shows that the first grounding grid 106 and the second grounding grid 108 are located on the same horizontal plane. In other embodiments, the first grounding grid 106 and the second grounding grid 108 can be located on different horizontal planes. For example, the first grounding grid 106 can be located above the second grounding grid 108. A person skilled in the art can understand that the heating plate 104 can include more grounding grids. These grounding grids cover different areas of the heating plate 104, and coverage areas of different grounding grids can overlap or not overlap. There can be various grounding grid configuration forms, which do not depart from the spirit or scope of the present invention.

The first grounding grid 106 is connected to a first heating plate radio-frequency electrode 110, and the second grounding grid 108 is connected to a second heating plate radio-frequency electrode 112. The first heating plate radio-frequency electrode 110 is connected to a first tuner 114 through some connection structures, and the second heating plate radio-frequency electrode 112 is connected to a second tuner 116 through some connection structures. The first heating plate radio-frequency electrode 110 and the second heating plate radio-frequency electrode 112 can be conductor rods (such as nickel rods or copper rods). One end of the conductor rod is connected to a corresponding grounding grid by means of welding or the like, and the other end of the conductor rod is connected to a corresponding tuner, so as to connect the corresponding tuner to the corresponding grounding grid. In an embodiment with more grounding grids, there can be a corresponding quantity of tuners connected to corresponding grounding grids. The first tuner 114 and the second tuner 116 can be any tuner adapted to adjust impedance of a radio-frequency loop. Either of the first tuner 114 and the second tuner 116 can include an adjustable capacitor and a sensor that is used for detecting a current.

The semiconductor processing apparatus 100 can further include a corrugated pipe 118 and a water cooling block 120 that are used for cooling the apparatus. For the purpose of simplifying the illustration, FIG. 1 shows only some components in the semiconductor processing apparatus 100, and a person skilled in the art should understand that the semiconductor processing apparatus 100 may further include other components not shown. In addition, a specific size, shape, position, and the like of each component shown in FIG. 1 are only for the purpose of illustration, and not for limitation. For example, the heating plate 104 may further include a heating element. In some embodiments, the heating element may correspond to a grounding grid. For example, a first heating element in the heating plate 104 may correspond to the first grounding grid 106. This means that the first heating element is located in an area covered by the first grounding grid 106 (for example, the central part of the heating plate 104). A second heating element in the heating plate 104 may correspond to the second grounding grid 108. This means that the second heating element is located in an area covered by the second grounding grid 108 (for example, the marginal part of the heating plate 104). In some other embodiments, the heating element does not need to correspond to a grounding grid. Each heating element may be connected to a corresponding pair of heating plate alternating current electrodes, and the pair of heating plate alternating current electrodes may be connected to a corresponding alternating current filter through some connection structures. The alternating current filter is configured to filter an alternating voltage supplied to the heating element.

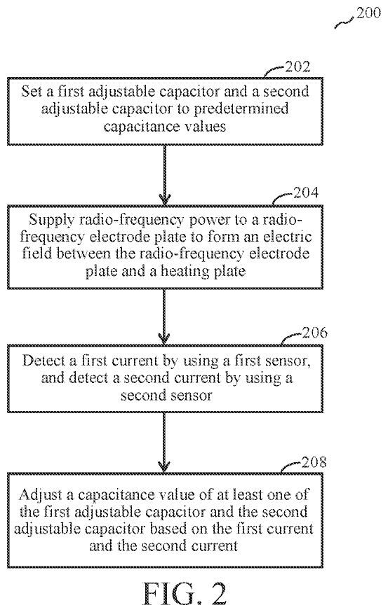

FIG. 2 is a flowchart of a method 200 for impedance adjustment of a single processing station according to some embodiments of this application. Although the method 200 is described in combination with the semiconductor processing apparatus 100 shown in FIG. 1, it should be understood that the method 200 may alternatively be performed by another device having a similar structure or function.

At step 202, a first adjustable capacitor in the first tuner 114 and a second adjustable capacitor in the second tuner 116 are set to predetermined capacitance values. The predetermined capacitance values may be selected according to processing requirements. In an embodiment, the predetermined capacitance values of the first adjustable capacitor and the second adjustable capacitor are the same. In other embodiments, the predetermined capacitance values of the first adjustable capacitor and the second adjustable capacitor are different. At step 204, radio-frequency power is applied to a radio-frequency electrode plate (such as the spray plate 102) to form an electric field between the radio-frequency electrode plate and the heating plate 104 for processing. At step 206, a first current is detected by using a first sensor in the first tuner 114, and a second current is detected by using a second sensor in the second tuner 116. The first sensor and the second sensor can detect high-frequency (such as 13.56 MHz or 27 MHz) current values. Because a high-frequency current value is directly proportional to the thickness of a formed film, the first current and the second current can reflect film thicknesses at positions corresponding to the first grounding grid 106 and the second grounding grid 108 respectively. At step 208, a capacitance value of at least one of the first adjustable capacitor and the second adjustable capacitor is adjusted based on the first current and the second current, so that the first current and the second current satisfy a predetermined relationship, so as to obtain required film thickness distribution. For example, to obtain a film with a uniform thickness in the central part and the marginal part, the predetermined relationship may be set as that the first current is equal to the second current; to obtain a film with the central part thicker than the marginal part, the predetermined relationship may be set as that the first current is greater than the second current; and to obtain a film with the central part thinner than the marginal part, the predetermined relationship may be set as that the first current is less than the second current. In some embodiments, the predetermined relationship may include that either or both of the first current and the second current are equal to a predetermined value or within a predetermined range.

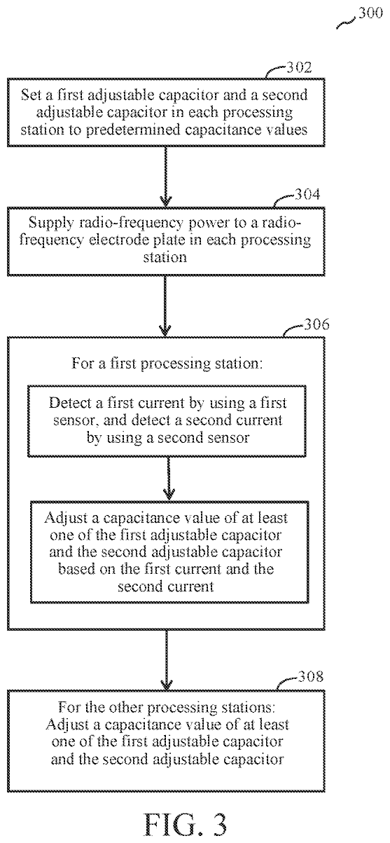

For a multi-station processing system, each processing station may include the semiconductor processing apparatus 100 shown in FIG. 1. FIG. 3 is a flowchart of a method 300 for impedance adjustment of a plurality of processing stations according to some embodiments of this application. Although the method 300 is described in combination with the semiconductor processing apparatus 100 shown in FIG. 1, it should be understood that the method 300 may alternatively be performed by another device having a similar structure or function. The method 300 can be applied to a plurality of processing stations located in the same processing chamber or to a plurality of processing stations located in different processing chambers.

At step 302, for each processing station, a first adjustable capacitor in the first tuner 114 and a second adjustable capacitor in the second tuner 116 are set to predetermined capacitance values. The predetermined capacitance values may be selected according to processing requirements. In an embodiment, predetermined capacitance values of all adjustable capacitors in tuners of all processing stations are the same. At step 304, radio-frequency power is supplied to a radio-frequency electrode plate (such as the spray plate 102) in each processing station to form an electric field between the radio-frequency electrode plate and the heating plate 104 in each processing station for processing. At step 306, the following operations are performed for a first processing station in the plurality of processing stations: detecting a first current by using a first sensor in the first tuner 114 of the first processing station; detecting a second current by using a second sensor in the second tuner 116 of the first processing station; and adjusting a capacitance value of at least one of the first adjustable capacitor and the second adjustable capacitor in the first processing station based on the first current and the second current, so that the first current and the second current satisfy a predetermined relationship, so as to obtain required film thickness distribution. For example, to obtain a film with a uniform thickness in the central part and the marginal part, the predetermined relationship may be set as that the first current is equal to the second current; to obtain a film with the central part thicker than the marginal part, the predetermined relationship may be set as that the first current is greater than the second current; and to obtain a film with the central part thinner than the marginal part, the predetermined relationship may be set as that the first current is less than the second current. In some embodiments, the predetermined relationship may include that either or both of the first current and the second current are equal to a predetermined value or within a predetermined range. The first current satisfying the predetermined relationship has a first value, and the second current satisfying the predetermined relationship has a second value. At step 308, the following operations are performed for each of the other processing stations in the plurality of processing stations: adjusting a capacitance value of at least one of the first adjustable capacitor and the second adjustable capacitor in the processing station, so that a current detected by a first sensor of the processing station has the first value, and a current detected by a second sensor of the processing station has the second value. In this way, the consistency of processing results of the processing stations can be ensured. In some embodiments, after the consistency of the processing stations is achieved through adjustment, when film thickness distribution of an individual processing station does not meet a requirement, at least one of the first adjustable capacitor and the second adjustable capacitor in tuners of the processing station may further be fine tuned.

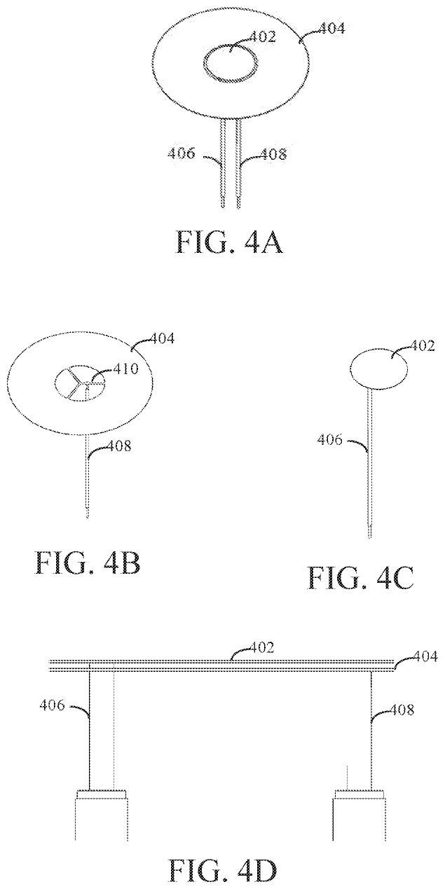

FIG. 4A to FIG. 4D are schematic structural diagrams of grounding grids according to some embodiments of this application. FIG. 4A shows a combination diagram of a first grounding grid 402 and a second grounding grid 404. FIG. 4B shows the second grounding grid 404 in FIG. 4A. FIG. 4C shows the first grounding grid 402 in FIG. 4A. FIG. 4D shows a locally enlarged diagram of the first grounding grid 402 and the second grounding grid 404 in FIG. 4A. In the example of FIG. 4A to FIG. 4D, the first grounding grid 402 and the second grounding grid 404 are arranged concentrically, and the first grounding grid 402 is above the second grounding grid 404. In some embodiments, a vertical distance between the first grounding grid 402 and the second grounding grid 404 is about 0.3 mm to 1 mm. A central part of the second grounding grid 404 includes a hollowed-out area at least partially covered by the first grounding grid 402, a connecting rib 410 is disposed in the hollowed-out area, a second heating plate radio-frequency electrode 408 is connected to the connecting rib 410, and a first heating plate radio-frequency electrode 406 is connected to the first grounding grid 402 through the hollowed-out area. In the combination diagram shown in FIG. 4A, the first heating plate radio-frequency electrode 406 and the second heating plate radio-frequency electrode 408 are symmetrically arranged relative to the center of the first grounding grid 402 and the second grounding grid 404. A coverage area of the first grounding grid 402 is smaller than the hollowed-out area of the central part of the second grounding grid 404. In an embodiment, a distance between an outer circumference of the first grounding grid 402 and an inner circumference of the second grounding grid 404 on a vertical projection plane is about 0.10 mm. A person skilled in the art should understand that the first grounding grid and the second grounding grid may have other different shapes and arrangements, which do not depart from the spirit or scope of the present invention.

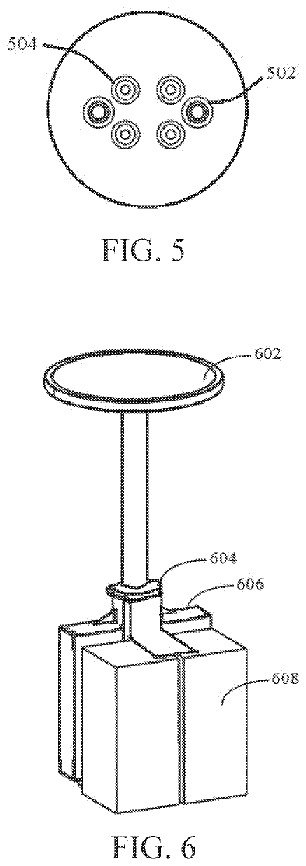

FIG. 5 shows a schematic arrangement diagram of heating plate electrodes according to some embodiments of this application. In the example of FIG. 5, the heating plate electrodes include two heating plate radio-frequency electrodes 502 and two pairs of heating plate alternating current electrodes 504. The heating plate alternating current electrodes are closer to the center of the heating plate than the heating plate radio-frequency electrodes. In an embodiment, a heating plate radio-frequency electrode 502 and a pair of heating plate alternating current electrodes 504 on the left side of FIG. 5 correspond to a first grounding grid (for example, the first grounding grid 402 in FIG. 4A to FIG. 4D), and a heating plate radio-frequency electrode 502 and a pair of heating plate alternating current electrodes 504 on the right side of FIG. 5 correspond to a second grounding grid (for example, the second grounding grid 404 in FIG. 4A to FIG. 4D). The arrangement shown in FIG. 5 can make positions of the heating plate electrodes relatively compact. In other embodiments, other quantities of heating plate radio-frequency electrodes and heating plate alternating current electrodes can be included, and other different arrangements can be used, which do not depart from the spirit or scope of the present invention.

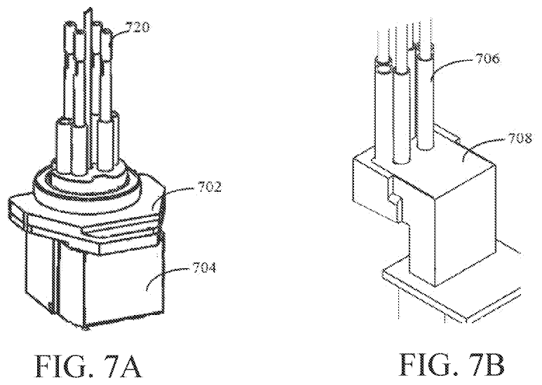

FIG. 6 is a schematic layout diagram of an alternating current filter 606 and a tuner 608 according to some embodiments of this application. The example of FIG. 6 includes two alternating current filters 606 placed side by side and two tuners 608 placed side by side. The alternating current filters 606 and the tuners 608 can be placed in any suitable manner, such as vertically or horizontally placed. The alternating current filters 606 and the tuners 608 are connected to a heating plate 602 by using an adapting structure 604.

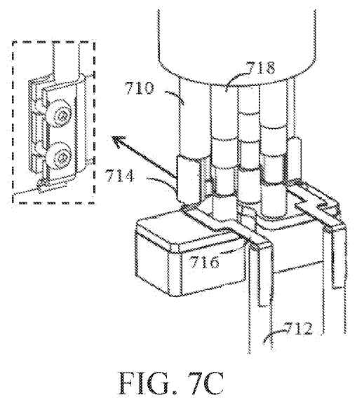

FIG. 7A to FIG. 7C show schematic diagrams of an adapting structure according to some embodiments of this application. An upper end of the adapting structure can be connected to a heating plate electrode, and a lower end of the adapting structure can be connected to an alternating current filter and a tuner. FIG. 7A shows a schematic three-dimensional structural diagram of the adapting structure. FIG. 7B shows a schematic structural diagram of the adapting structure shown in FIG. 7A after a housing 702 used for shielding radio frequencies is removed. FIG. 7C shows a schematic structural diagram of the adapting structure shown in FIG. 7B after an isolation block 708 is removed, and further shows a connection mode between the adapting structure and the heating plate electrodes. The adapting structure shown in FIG. 7A to FIG. 7C includes the housing 702, isolation component(s), a radio-frequency adapting structure, and an alternating current adapting structure 720.

The housing 702 is used for shielding radio frequencies, and is also a part of a radio-frequency loop. For example, a ground terminal of the tuner can be connected to the housing 702 to form the radio-frequency loop. The housing 702 further includes a window 704 used for operating and checking the interior of the adapting structure. The interior of the adapting structure can be exposed by removing a housing portion at the window 704.

The isolation component(s) includes (include) isolation tube(s) 706, the isolation block(s) 708, or the like. The isolation component isolates the alternating current adapting structure from the radio-frequency adapting structure, so that a radio-frequency path can be operated and checked in a live-line condition. The isolation component (such as the isolation tube 706) may surround the alternating current adapting structure. The isolation component (such as the isolation block 708) may surround the radio-frequency adapting structure. In some embodiments, the isolation component includes a radio-frequency insulation material such as polyether ether ketone (PEEK) or ceramics. In some embodiments, the thickness of an insulation tube or insulation block is greater than or equal to 1 mm. A structure of a contact intersection part surrounded by the isolation component uses a snap-in isolation mode.

The radio-frequency adapting structure is configured to connect a heating plate radio-frequency electrode 710 to an access electrode 712 of the tuner. In the example of FIG. 7C, the radio-frequency adapting structure includes a clamping structure 714 and a spring plate 716. One end of the spring plate 716 is fastened to the access electrode 712 of the tuner by using, for example, screws or similar structures. The other end of the spring plate 716 is clamped and connected to the heating plate radio-frequency electrode 710 by using the clamping structure 714. A horizontal extension part is included between the two ends of the spring plate 716. An enlarged diagram of the clamping structure 714 is shown in a dashed box of FIG. 7C. The heating plate radio-frequency electrode 710 may elongate when a temperature rises and may shorten when the temperature drops. The clamping structure 714 can avoid a relative movement between the heating plate radio-frequency electrode 710 and the radio-frequency adapting structure caused by a temperature change. The spring plate 716 can buffer the deformation of the heating plate radio-frequency electrode 710 caused by the temperature change. In some embodiments, the radio-frequency adapting structure includes copper or silver, or other material that facilitates radio-frequency conduction. To achieve better radio-frequency conduction, a surface of the radio-frequency adapting structure is plated with material that facilitates radio-frequency conduction, such as nickel, gold, or silver. Preferably, a plating technique of the radio-frequency adapting structure includes a composite film, for example, gold, silver, or the like can be plated after nickel plating. In some embodiments, the spring plate 716 includes beryllium copper or other highly elastic material. The material has a long service life and can meet the requirement of many times of deformation. In some embodiments, the clamping structure 714 includes copper. To meet the requirement of transmitting a radio-frequency signal, surfaces of the clamping structure 714 and the spring plate 716 can be plated with nickel (for example, 2 μm) and then plated with gold or silver (for example, 5 μm). An internal structure of the isolation block 708 surrounding the radio-frequency adapting structure is designed to limit a movement direction of the clamping structure 714, so that the clamping structure 714 can only move up and down with the shortening and elongation of the heating plate radio-frequency electrode 710, and cannot move horizontally.

The alternating current adapting structure 720 is configured to connect a heating plate alternating current electrode 718 to an electrode interface of the alternating current filter. In the example of FIG. 7A to FIG. 7C, one end of the alternating current adapting structure 720 that is connected to the heating plate alternating current electrode 718 includes a female connector structure with a wire spring inside, so that the heating plate alternating current electrode 718 can be directly inserted into the alternating current adapting structure 720 and fastened for connection. The other end of the alternating current adapting structure 720 includes a male connector structure, so that the alternating current adapting structure 720 can be directly inserted into the electrode interface of the alternating current filter and fastened for connection. This connection mode can avoid a problem that arises when the alternating current filter and the heating plate are connected by a wire, i.e., impedance of the wire is less than impedance between the spray plate and the heating plate under some working conditions, resulting in radio frequencies flowing into a line of the alternating current filter and not acting on gas to produce plasma. In some embodiments, the alternating current adapting structure 720 includes copper or other similar conductive material, and the surface of the alternating current adapting structure 720 can be plated with gold, silver, or the like after nickel plating.

In the example shown in FIG. 7C, a position at which the alternating current adapting structure 720 is connected to the electrode interface of the alternating current filter is below and behind a position at which the radio-frequency adapting structure is connected to the access electrode 712 of the tuner. The alternating current adapting structure 720 and the radio-frequency adapting structure use space alternately, so that the adapting structure is compact and practical.

In the embodiments of this application, the adapting structure connects the alternating current filter and the tuner directly to the heating plate electrode, so that the alternating current filter and the tuner can move up and down with the heating plate, thereby avoiding an impedance change caused by a relative movement.

This application provides apparatuses, systems, and methods for impedance adjustment of a processing station(s), so that film thickness distribution of a single station and film performance differences between a plurality of stations can be well adjusted, thereby providing good production quality and efficiency and creating good production economic value. The apparatuses, the systems, and the methods described in this application can be applied to a 3D semiconductor processing technique, an atomic layer deposition technique, a plasma-enhanced chemical vapor deposition technique, or other similar techniques. For example, the apparatuses in this application can be applied to plasma vapor deposition devices of 13.56 MHz+400 kHz and 27 MHz+400 kHz dual frequency systems and radio-frequency systems of other frequencies.

The description in this specification is provided to enable those skilled in the art to implement or use the present invention. Modifications to the present invention are readily apparent to those skilled in the art, and the general principles defined in this specification can be applied to other variations without departing from the spirit or scope of the present invention. Therefore, the present invention is not limited to the examples and designs described in this specification, but is given the widest scope consistent with the principles and novel features disclosed in this specification.

1. An apparatus for impedance adjustment of a single processing station, comprising:
a heating plate comprising a first grounding grid and a second grounding grid, wherein the first grounding grid and the second grounding grid cover different areas of the heating plate;
a first tuner connected to the first grounding grid and comprising a first adjustable capacitor and a first sensor for detecting a current; and
a second tuner connected to the second grounding grid and comprising a second adjustable capacitor and a second sensor for detecting a current.

2. The apparatus according to claim 1, further comprising:
a first heating plate radio-frequency electrode, wherein one end of the first heating plate radio-frequency electrode is connected to the first grounding grid, and the other end of the first heating plate radio-frequency electrode is connected to the first tuner; and
a second heating plate radio-frequency electrode, wherein one end of the second heating plate radio-frequency electrode is connected to the second grounding grid, and the other end of the second heating plate radio-frequency electrode is connected to the second tuner.

3. The apparatus according to claim 2, wherein the first heating plate radio-frequency electrode and the second heating plate radio-frequency electrode are nickel rods or copper rods.

4. The apparatus according to claim 2, wherein the first grounding grid and the second grounding grid are arranged concentrically.

5. The apparatus according to claim 4, wherein the first heating plate radio-frequency electrode and the second heating plate radio-frequency electrode are symmetrically arranged relative to the center of the first grounding grid and the second grounding grid.

6. The apparatus according to claim 4, wherein the first grounding grid is above the second grounding grid, a central part of the second grounding grid comprises a hollowed-out area at least partially covered by the first grounding grid, a connecting rib is disposed in the hollowed-out area, the second heating plate radio-frequency electrode is connected to the connecting rib, and the first heating plate radio-frequency electrode is connected to the first grounding grid through the hollowed-out area.

7. The apparatus according to claim 2, further comprising an adapting structure comprising:
a first radio-frequency adapting structure connecting the other end of the first heating plate radio-frequency electrode to a first access electrode of the first tuner; and
a second radio-frequency adapting structure connecting the other end of the second heating plate radio-frequency electrode to a second access electrode of the second tuner.

8. The apparatus according to claim 7, wherein:
the first radio-frequency adapting structure comprises a first clamping structure and a first spring plate, wherein one end of the first spring plate is fastened to the first access electrode, and the other end of the first spring plate is clamped and connected to the other end of the first heating plate radio-frequency electrode by using the first clamping structure; and
the second radio-frequency adapting structure comprises a second clamping structure and a second spring plate, wherein one end of the second spring plate is fastened to the second access electrode, and the other end of the second spring plate is clamped and connected to the other end of the second heating plate radio-frequency electrode by using the second clamping structure.

9. The apparatus according to claim 8, wherein a first horizontal extension part is comprised between the one end of the first spring plate and the other end of the first spring plate, and a second horizontal extension part is comprised between the one end of the second spring plate and the other end of the second spring plate.

10. The apparatus according to claim 7, wherein the first radio-frequency adapting structure and the second radio-frequency adapting structure comprise copper or silver.

11. The apparatus according to claim 7, wherein surfaces of the first radio-frequency adapting structure and the second radio-frequency adapting structure are plated with at least one of nickel, gold, and silver.

12. The apparatus according to claim 7, wherein the adapting structure further comprises an alternating current adapting structure, wherein one end of the alternating current adapting structure is connected to a heating plate alternating current electrode, the heating plate alternating current electrode is connected to a heating element in the heating plate, and the other end of the alternating current adapting structure is connected to an electrode interface of an alternating current filter.

13. The apparatus according to claim 12, wherein a position at which the other end of the alternating current adapting structure is connected to the electrode interface of the alternating current filter is below a position at which the first radio-frequency adapting structure is connected to the first access electrode.

14. The apparatus according to claim 12, wherein the heating plate alternating current electrode comprises:
a first pair of heating plate alternating current electrodes connected to a first heating element in the heating plate; and
a second pair of heating plate alternating current electrodes connected to a second heating element in the heating plate.

15. The apparatus according to claim 14, wherein the first heating element corresponds to the first grounding grid, and the second heating element corresponds to the second grounding grid.

16. The apparatus according to claim 12, wherein the adapting structure further comprises an isolation component isolating the alternating current adapting structure from the first radio-frequency adapting structure and the second radio-frequency adapting structure.

17. The apparatus according to claim 16, wherein the isolation component surrounds the alternating current adapting structure.

18. The apparatus according to claim 16, wherein the isolation component surrounds the first radio-frequency adapting structure and the second radio-frequency adapting structure.

19. The apparatus according to claim 16, wherein the isolation component comprises an isolation tube or an isolation block.

20. The apparatus according to claim 7, wherein the adapting structure further comprises a housing for shielding radio frequencies.

21. The apparatus according to claim 20, wherein the housing comprises a window used for operating and checking the interior of the adapting structure.

22. A system for impedance adjustment of a plurality of processing stations, comprising:
a plurality of apparatuses according to claim 1, wherein each apparatus is in one processing station.

23. A method for impedance adjustment of a single processing station, wherein the processing station comprises the apparatus according to claim 1, and a radio-frequency electrode plate opposite to the heating plate, and the method comprises:
setting the first adjustable capacitor and the second adjustable capacitor to predetermined capacitance values;
supplying radio-frequency power to the radio-frequency electrode plate to form an electric field between the radio-frequency electrode plate and the heating plate;
detecting a first current by using the first sensor;
detecting a second current by using the second sensor; and
adjusting a capacitance value of at least one of the first adjustable capacitor and the second adjustable capacitor based on the first current and the second current, so that the first current and the second current satisfy a predetermined relationship.

24. The method according to claim 23, wherein the predetermined relationship comprises that the first current is equal to the second current, the first current is greater than the second current, or the first current is less than the second current.

25. The method according to claim 23, wherein the predetermined relationship comprises that either or both of the first current and the second current are equal to a predetermined value or within a predetermined range.

26. A method for impedance adjustment of a plurality of processing stations, wherein each of the plurality of processing stations comprises the apparatus according to claim 1, and a radio-frequency electrode plate opposite to the heating plate, and the method comprises:
setting the first adjustable capacitor and the second adjustable capacitor in each processing station to predetermined capacitance values;
supplying radio-frequency power to the radio-frequency electrode plate in each processing station to form an electric field between the radio-frequency electrode plate and the heating plate in each processing station;
performing the following operations for a first processing station in the plurality of processing stations:
detecting a first current by using the first sensor of the first processing station;
detecting a second current by using the second sensor of the first processing station; and
adjusting a capacitance value of at least one of the first adjustable capacitor and the second adjustable capacitor in the first processing station based on the first current and the second current, so that the first current and the second current satisfy a predetermined relationship, wherein the first current satisfying the predetermined relationship has a first value, and the second current satisfying the predetermined relationship has a second value; and
performing the following operations for each of the other processing stations in the plurality of processing stations:
adjusting a capacitance value of at least one of the first adjustable capacitor and the second adjustable capacitor in the processing station, so that a current detected by the first sensor of the processing station has the first value, and a current detected by the second sensor of the processing station has the second value.

27. The method according to claim 26, wherein the predetermined relationship comprises that the first value is equal to the second value, the first value is greater than the second value, or the first value is less than the second value.

28. The method according to claim 26, wherein the predetermined relationship comprises that either or both of the first value and the second value are equal to a predetermined value or within a predetermined range.

29. The method according to claim 26, further comprising: after a current detected by the first sensor of a second processing station in the plurality of processing stations has the first value and a current detected by the second sensor of the second processing station has the second value, fine tuning at least one of the first adjustable capacitor and the second adjustable capacitor in the second processing station.
